(19) United States
(12) Patent Application Publication
(10) Pub. No.: US 2025/0085626 A1
(43) Pub. Date: Mar. 13, 2025

(54) ALIGNMENT FORMING METHOD FOR HOLOGRAM FILM

(71) Applicant: K LASER Technology Inc., HSINCHU (TW)

(72) Inventor: Kung Linliu, HSINCHU (TW)

(21) Appl. No.: 18/244,946

(22) Filed: Sep. 12, 2023

(51) Int. Cl. G03F 7/00; G03H 1/04

(52) U.S. Cl. CPC G03F 7/001; G03H 1/0486

(57) ABSTRACT

An alignment forming method for a hologram film includes a preparing step and an embossing and solidifying step. The preparing step is implemented by providing an embossing mask and an alignment carrier. The embossing mask has a unit pattern layer and a plurality of mask alignment marks. The alignment carrier has a plurality of carrier alignment marks and defines a plurality of embossed regions. The embossing and solidifying step is implemented by sequentially placing a plurality of ultraviolet (UV) solidified resins onto the embossed regions, respectively, and sequentially embossing the UV solidified resins through the unit pattern layer to enable the UV solidified resins to respectively have a plurality of hologram unit patterns. Specifically, when one of the UV solidified resins is embossed, the one of the UV solidified resins is solidified to form one of the hologram unit patterns by a solidifying UV light.

### FIELD OF THE DISCLOSURE

The present disclosure relates to a forming method for an optical film, and more particularly to an alignment forming method for a hologram film.

### BACKGROUND OF THE DISCLOSURE

A conventional forming method for a hologram film is implemented in a rolling manner. However, since the rolling manner has its inherent limitations, the conventional forming method is difficult to be significantly improved or further developed.

### SUMMARY OF THE DISCLOSURE

In response to the above-referenced technical inadequacy, the present disclosure provides an alignment forming method for a hologram film to effectively improve on the issues associated with conventional forming methods.

In order to solve the above-mentioned problems, one of the technical aspects adopted by the present disclosure is to provide an alignment forming method for a hologram film, which includes a preparing step and an embossing and solidifying step. The preparing step is implemented by providing an embossing mask and an alignment carrier. The embossing mask includes a plate and a unit pattern layer that is formed on the plate. The plate has a plurality of mask alignment marks corresponding in position to the unit pattern layer. The alignment carrier has a plurality of carrier alignment marks. The alignment carrier defines a plurality of embossed regions through the carrier alignment marks. The embossing and solidifying step is implemented by sequentially placing a plurality of ultraviolet (UV) solidified resins onto the embossed regions, respectively, and sequentially embossing the UV solidified resins in a plurality of embossing processes to enable the UV solidified resins to respectively have a plurality of hologram unit patterns. One of the embossing processes is implemented by aligning the mask alignment marks of the embossing mask with at least two of the carrier alignment marks arranged adjacent to one of the UV solidified resins along a height direction, and then embossing the one of the UV solidified resins along the height direction through the unit pattern layer of the embossing mask so as to enable the one of the UV solidified resins to have a predetermined unit pattern. In the embossing and solidifying step, when the one of the UV solidified resins is embossed through the embossing mask, the predetermined unit pattern of the one of the UV solidified resins is solidified to form one of the hologram unit patterns by a solidifying UV light. The UV solidified resins are spaced apart from each other, and any two of the UV solidified resins adjacent to each other have an alignment gap therebetween that is less than or equal to 5 μm and that is provided for allowing at least one of the carrier alignment marks to be exposed therefrom.

Therefore, the alignment forming method provided by the present disclosure can be implemented to rapidly form the hologram unit patterns without using the conventional rolling manner, and can be implemented to precisely form the hologram unit patterns through the cooperation between the mask alignment marks of the embossing mask and the carrier alignment marks of the alignment carrier.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of an alignment forming apparatus according to a first embodiment of the present disclosure;

FIG. 2 is a schematic view showing a preparing step of an alignment forming method according to the first embodiment of the present disclosure;

FIG. 3 to FIG. 6 are schematic views showing an embossing and solidifying step of the alignment forming method according to the first embodiment of the present disclosure;

FIG. 7 is a schematic view showing a mask correcting step of the alignment forming method according to the first embodiment of the present disclosure;

FIG. 8 is a schematic perspective view of a part of the alignment forming apparatus according to a second embodiment of the present disclosure;

FIG. 9 is a schematic view showing a flattening step of the alignment forming method according to the second embodiment of the present disclosure; and

FIG. 10 is a schematic view showing the embossing and solidifying step of the alignment forming method according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

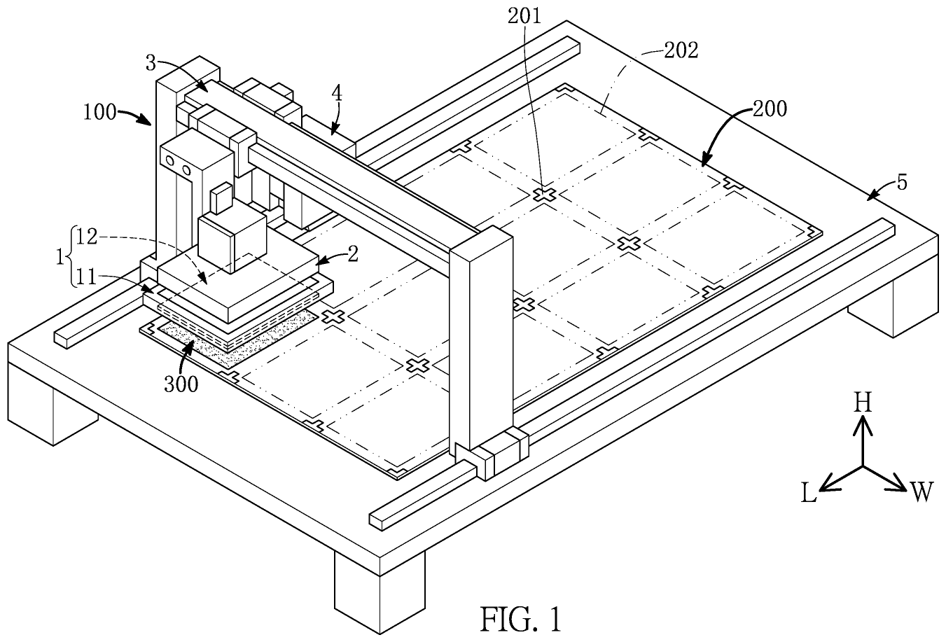

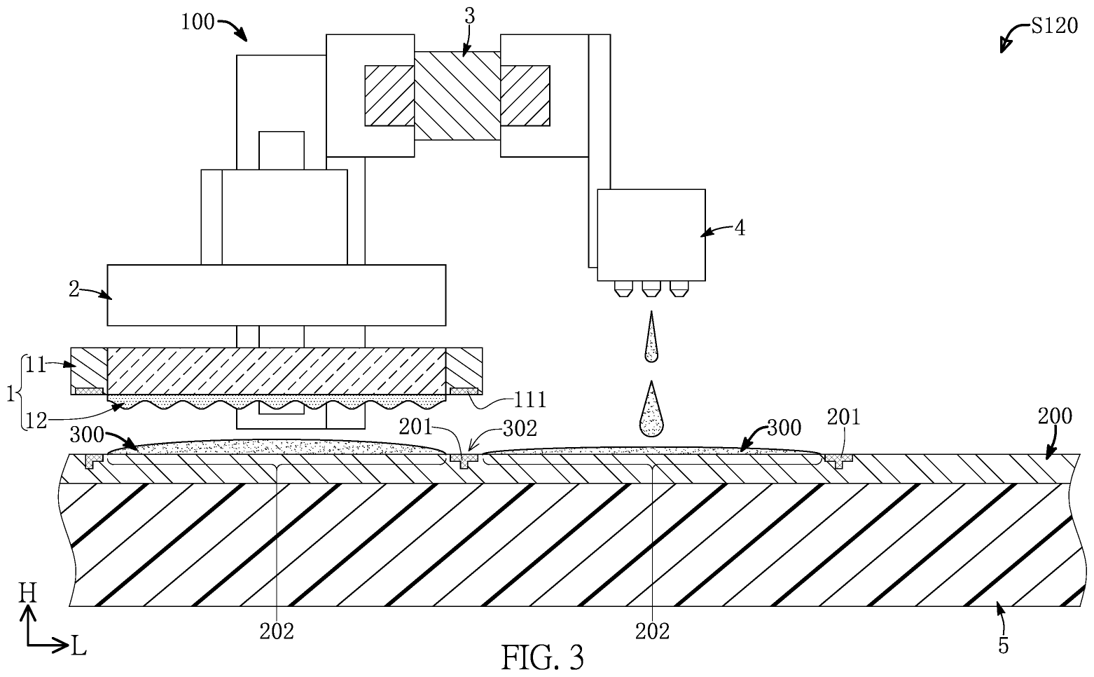

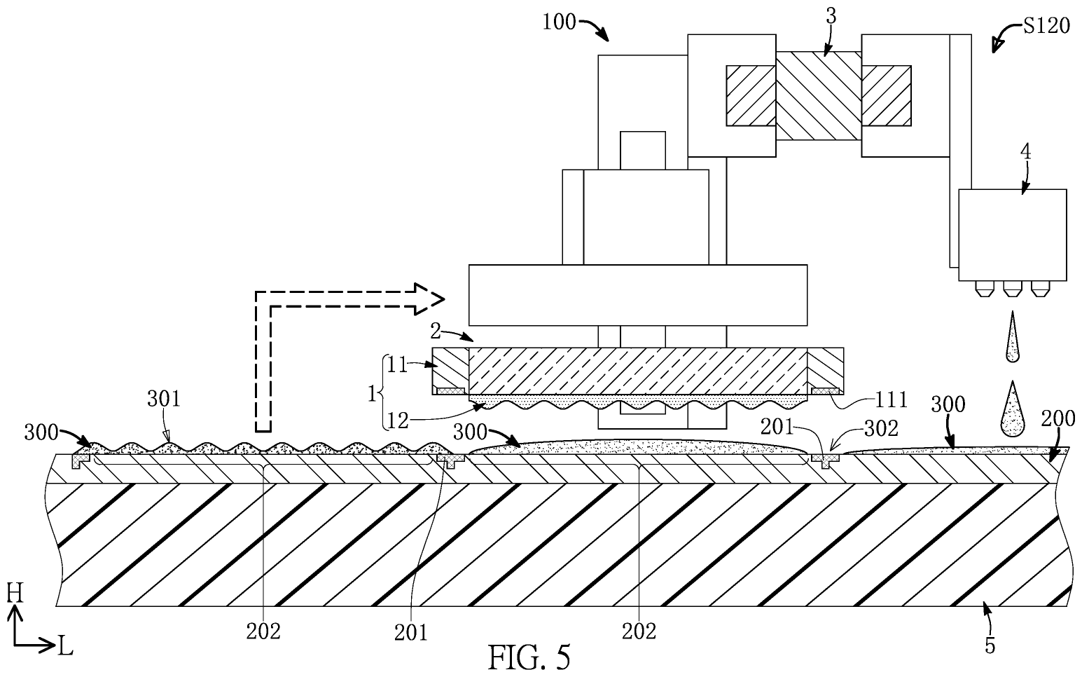

Referring to FIG. 1 to FIG. 7, a first embodiment of the present disclosure is provided. As shown in FIG. 1, the present embodiment provides an alignment forming method and an alignment forming apparatus 100 each applied for a hologram film. In order to clearly describe the present embodiment, the following description first describes the alignment forming apparatus 100, and then describes the alignment forming method.

It should be noted that the alignment forming method in the present embodiment is implemented by using the alignment forming apparatus 100, but the present disclosure is not limited thereto. For example, in other embodiments of the present disclosure not shown in the drawings, the alignment forming method can be implemented through using other apparatuses.

As shown in FIG. 1 to FIG. 3, the alignment forming apparatus 100 in the present embodiment includes a platform 5, a displacement mechanism 3 disposed on the platform 5, a dispensing mechanism 4 arranged corresponding to the platform 5, an embossing mask 1 connected to the displacement mechanism 3, and a solidifying light source 2 that is connected to the displacement mechanism 3 and that is arranged corresponding to the embossing mask 1. The alignment forming apparatus 100 in the present embodiment is described according to the above components, but the present disclosure is not limited thereto. For example, in other embodiments of the present disclosure not shown in the drawings, the solidifying light source 2 can be omitted or can be replaced with other components.

The platform 5 allows an alignment carrier 200 to be disposed thereon. The alignment carrier 200 in the present embodiment has a flat shape and has a plurality of carrier alignment marks 201, and the alignment carrier 200 defines a plurality of embossed regions 202 through the carrier alignment marks 201 (e.g., any one of the embossed regions 202 has a rectangular shape that has four corners respectively defined by four of the carrier alignment marks 201). It should be noted that the embossed regions 202 in the present embodiment are spaced apart from each other, and any two of the embossed regions 202 adjacent to each other have a spacing therebetween that is preferably less than or equal to 5 μm, but the present disclosure is not limited thereto.

The displacement mechanism 3 is movable relative to the platform 5 along a height direction H, a transverse direction W, and a longitudinal direction L. The height direction H, the transverse direction W, and the longitudinal direction L are preferably orthogonal to each other. In the present embodiment, the dispensing mechanism 4, the embossing mask 1, and the solidifying light source 2 are assembled to the displacement mechanism 3, so that any one of the dispensing mechanism 4, the embossing mask 1, and the solidifying light source 2 can be moved along the height direction H, the transverse direction W, and the longitudinal direction L through the displacement mechanism 3. Moreover, the embossing mask 1 and the solidifying light source 2 in the present embodiment are synchronously moved through the displacement mechanism 3, but the present disclosure is not limited thereto.

The embossing mask 1 includes a plate 11 and a unit pattern layer 12 that is formed on the plate 11. The unit pattern layer 12 is formed on an outer surface of the plate 11 in an ultraviolet light exposure manner and a development manner. The plate 11 has a plurality of mask alignment marks 111 corresponding in position to the unit pattern layer 12 (e.g., the unit pattern layer 12 is arranged inside of the mask alignment marks 111).

The above description briefly describes the alignment forming apparatus 100, and the following description describes the alignment forming method implemented by using the alignment forming apparatus 100, but the present disclosure is not limited thereto. In the present embodiment, the alignment forming method mainly includes a preparing step S110 and an embossing and solidifying step S120.

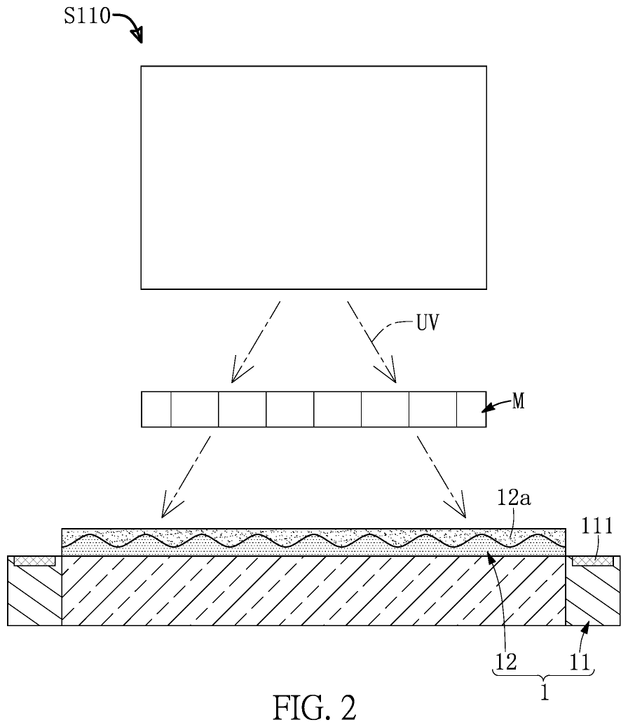

As shown in FIG. 1 and FIG. 2, the preparing step S110 is implemented to manufacture the embossing mask 1 by coating a photoresist layer 12a onto the outer surface of the plate 11 and then using an exposure ultraviolet light to irradiate onto the photoresist layer 12a through a mask M or an interference, such that the photoresist layer 12a is formed to be the unit pattern layer 12. In other words, the plate 11 and the unit pattern layer 12 formed thereon in the present embodiment are jointly defined as the embossing mask 1.

It should be noted that the plate 11 of the present embodiment has a light-permeable function that can be provided by using a light-permeable material to form the plate 11 or that can be provided by forming a thru-hole on the plate 11. For example, the plate 11 can be made of a glass or can be a silicone carrier having a thru-hole, and the preparing step S110 is preferably implemented without using any nickel metal, but the present disclosure is not limited thereto.

As shown in FIG. 1 and FIG. 3 to FIG. 6, the embossing and solidifying step S120 is implemented by sequentially placing a plurality of ultraviolet solidified resins 300 onto the embossed regions 202, respectively, and sequentially embossing the ultraviolet solidified resins 300 in a plurality of embossing processes to enable the ultraviolet solidified resins 300 to respectively have a plurality of hologram unit patterns 301. Each of the embossing processes is implemented by aligning the mask alignment marks 111 of the embossing mask 11 with at least two of the carrier alignment marks 201 arranged adjacent to one of the ultraviolet solidified resins 300 along the height direction H, and then embossing the one of the ultraviolet solidified resins 300 along the height direction H through the unit pattern layer 12 of the embossing mask 1 so as to enable the one of the ultraviolet solidified resins 300 to have a predetermined unit pattern. Moreover, when the one of the ultraviolet solidified resins 300 is embossed through the embossing mask 1, the predetermined unit pattern of the one of the ultraviolet solidified resins 300 is solidified to form one of the hologram unit patterns 301 by a solidifying ultraviolet light 21. The hologram unit patterns 301 in the present embodiment can be in a matrix arrangement, but the present disclosure is not limited thereto.

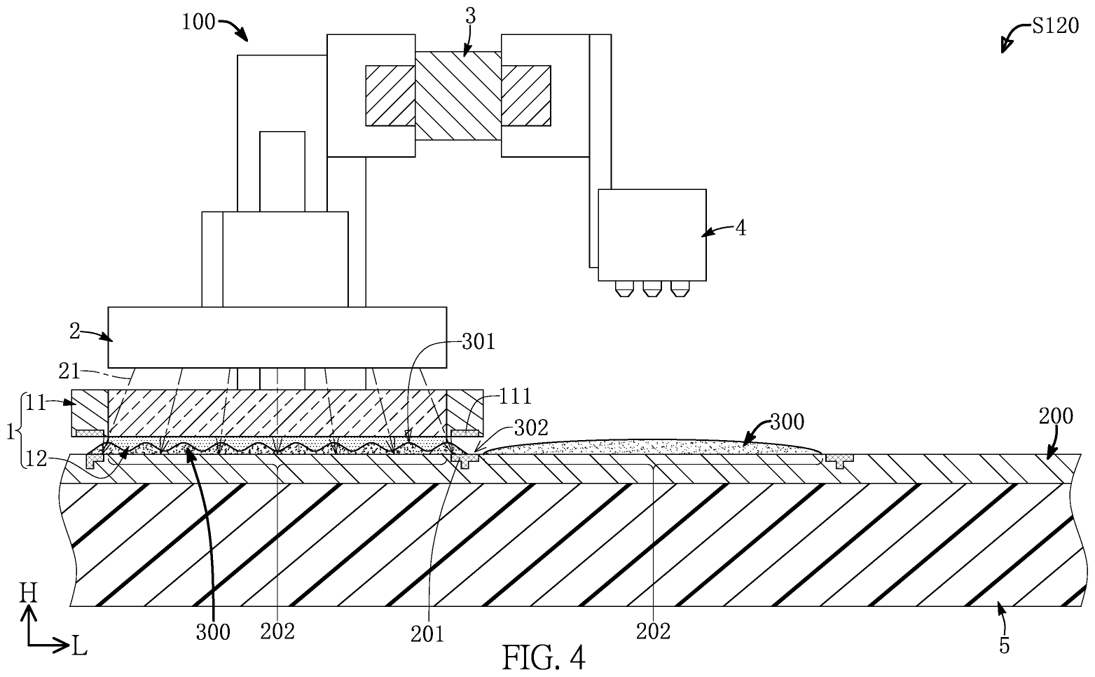

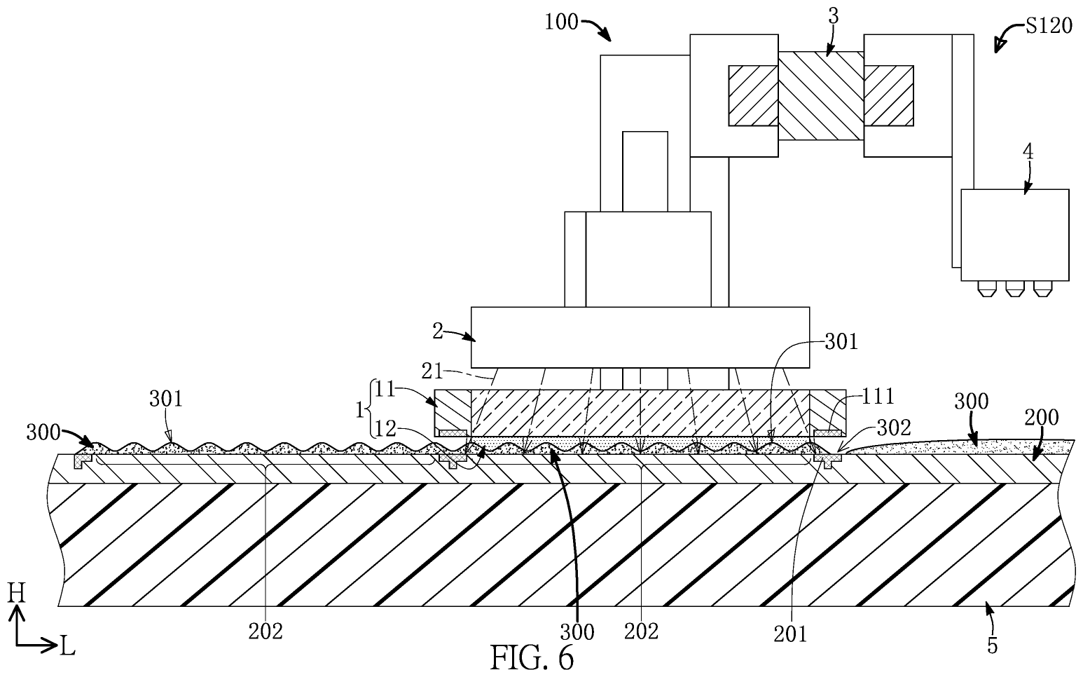

Specifically, the ultraviolet solidified resins 300 are preferably spaced apart from each other, and any two of the ultraviolet solidified resins 300 adjacent to each other have an alignment gap 302 therebetween that is less than or equal to 5 μm and that is provided for allowing at least one of the carrier alignment marks 201 to be exposed therefrom. Moreover, in any two of the embossing processes (as shown in FIG. 4 and FIG. 6), two of the ultraviolet solidified resins 300 are embossed to flow outwardly and fill the alignment gap 302 therebetween for covering a corresponding one of the carrier alignment marks 201.

In other words, when the alignment forming apparatus 100 is used, the dispensing mechanism 4 is configured to sequentially place the ultraviolet solidified resins 300 onto the embossed regions 202, respectively. In other words, the dispensing mechanism 4 is configured to form the ultraviolet solidified resins 300 that are placed on the alignment carrier 200 and that are spaced apart from each other. The alignment gap 302 between any two of the ultraviolet solidified resins 300 adjacent to each other can be precisely controlled and maintained to be less than or equal to 5 μm, thereby meeting more pattern formation requirements.

Moreover, the alignment forming apparatus 100 can be used to implement each of the embossing processes. In other words, the alignment forming apparatus 100 can be operated for aligning the mask alignment marks 111 of the embossing mask 11 with at least two of the carrier alignment marks 201 arranged adjacent to one of the ultraviolet solidified resins 300 along the height direction H, and then embossing the one of the ultraviolet solidified resins 300 along the height direction H through the unit pattern layer 12 of the embossing mask 1 so as to enable the one of the ultraviolet solidified resins 300 to have the predetermined unit pattern. Furthermore, the solidifying light source 2 can emit a solidifying ultraviolet light 21 that has a wavelength in a predetermined solidifying wavelength band and that travels toward and solidifies the one of the ultraviolet solidified resins 300 being embossed by the embossing mask 1 for enabling the predetermined unit pattern to be formed as the hologram unit pattern.

In order to prevent the unit pattern layer 12 of the embossing mask 1 from being irradiated and damaged by the solidifying ultraviolet light 21, the predetermined exposing wavelength of the exposure ultraviolet light UV is preferably not in the predetermined solidifying wavelength band of the solidifying ultraviolet light 21, but the present disclosure is not limited thereto. In the present embodiment, the predetermined exposing wavelength of the exposure ultraviolet light UV is less than the predetermined solidifying wavelength band of the solidifying ultraviolet light 21 by at least 100 nm. For example, the predetermined exposing wavelength can be within a range from 190 nm to 250 nm, and the predetermined solidifying wavelength band is preferably from 350 nm to 410 nm, but the present disclosure is not limited thereto.

In summary, the embossing and solidifying step S120 in the present embodiment is implemented by using the dispensing mechanism 4, the embossing mask 1, and the solidifying light source 2 of the alignment forming apparatus 100, which have operation periods that are partially overlapped (e.g., when a N^{th} one of the ultraviolet solidified resins 300 is embossed through the embossing mask 1, the N^{th} one of the ultraviolet solidified resins 300 is simultaneously solidified through the solidifying light source 2, and a N+1^{th} one of the ultraviolet solidified resins 300 can be simultaneously formed on the corresponding embossed region 202 through the dispensing mechanism 4, in which N is a positive integer greater than one), thereby increasing an operation performance of the alignment forming apparatus 100, but the present disclosure is not limited thereto.

Accordingly, the alignment forming method provided by the present embodiment can be implemented to rapidly form the hologram unit patterns 301 without using the conventional rolling manner, and can be implemented to precisely form the hologram unit patterns 301 (e.g., a tolerance of any one of the hologram unit patterns 301 is less than 5 μm, which is better than a tolerance of conventional hologram unit pattern within a range from 100 μm to 400 μm) through the cooperation between the mask alignment marks 111 of the embossing mask 1 and the carrier alignment marks 201 of the alignment carrier 200.

Specifically, the alignment carrier 200 and the hologram unit patterns 301 formed thereof can be used as a mother mold to form (e.g., emboss) a plurality of child molds, and any one of the child molds is used to form (e.g., emboss) a plurality of optical films (i.e., hologram film products) for consumers. In other words, the alignment forming method or the alignment forming apparatus 100 can be regarded as providing for manufacturing a hologram mother mold, but the present disclosure is not limited thereto.

Moreover, when the hologram unit pattern 301 has a distortion that is unacceptable relative to the predetermined unit pattern, the alignment forming method can be implemented to fine-tune or fix the distortion of the hologram unit pattern 301. It should be noted that the distortion does not always occur, but the alignment forming method of the present embodiment has a function being capable of fine-tuning or fixing the distortion.

Specifically, as shown in FIG. 1 and FIG. 6, when one of the hologram unit patterns 301 has a distortion that is unacceptable relative to the predetermined unit pattern, the embossing and solidifying step S120 can be implemented to fine-tune or fix the distortion. Specifically, when another one of the ultraviolet solidified resins 300 is embossed through the embossing mask 1, the hologram unit pattern 301 of the another one of the ultraviolet solidified resins 300 is solidified by the solidifying ultraviolet light 21 that has an intensity distribution adjusted by an optical proximity correction (OPC) process according to the predetermined unit pattern (e.g., an outside portion of the solidifying ultraviolet light 21 shown in FIG. 6 can be enhanced), thereby fine-tuning or fixing the distortion.

In other words, when the alignment forming apparatus 100 is used, the solidifying light source 2 can be used to implement the OPC process by adjusting the intensity distribution of the solidifying ultraviolet light 21 emitted therefrom according to the predetermined unit pattern, thereby fine-tuning or fixing the distortion.

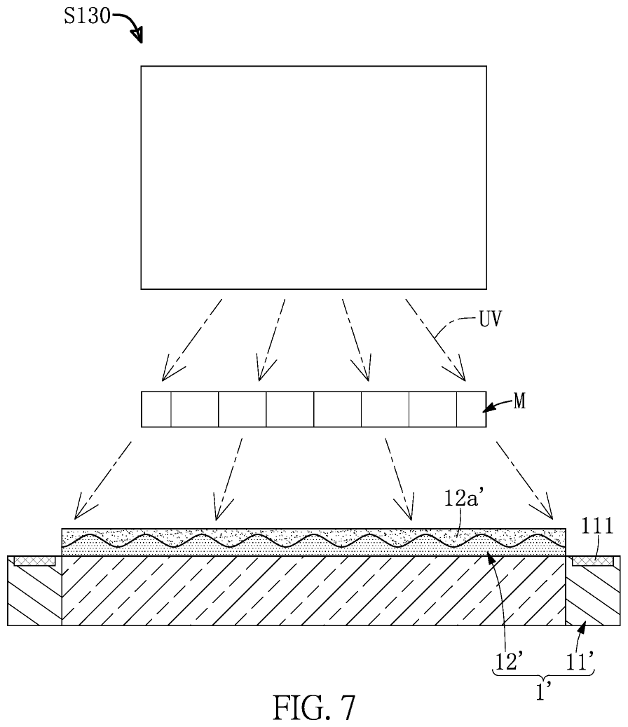

As shown in FIG. 6 and FIG. 7, when one of the hologram unit patterns 301 has a distortion that is unacceptable relative to the predetermined unit pattern, the embossing mask 1 can be adjusted or changed to fine-tune or fix the distortion. Specifically, after the embossing and solidifying step S120 is implemented, the alignment forming method further includes a mask correcting step S130 implemented by using the OPC process to manufacture a corrected embossing mask 1′ according to the predetermined unit pattern, and then the corrected embossing mask 1′ is used to implement the embossing and solidifying step S120 (not shown in the drawings) for another hologram film.

Moreover, the mask correcting step S130 includes: forming another photoresist layer 12a′ on an outer surface of another plate 11′; adjusting an intensity distribution of the exposure ultraviolet light UV through the OPC process (e.g., an outside portion of the exposure ultraviolet light UV shown in FIG. 7 can be enhanced); and using the exposure ultraviolet light UV being adjusted to have a predetermined light shape through the mask M or the interference, and then irradiating the exposure ultraviolet light UV having the predetermined light shape onto the another photoresist layer 12a′ for forming a corrected unit pattern layer 12′. The corrected unit pattern layer 12′ and the another plate 11′ are jointly formed as the corrected embossing mask 1′.

### Second Embodiment

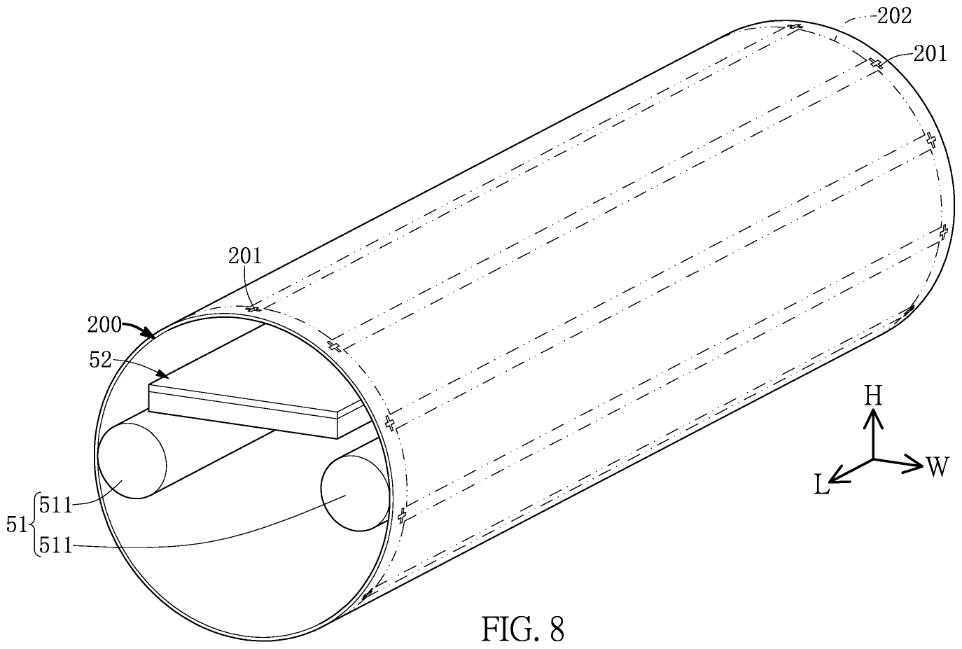

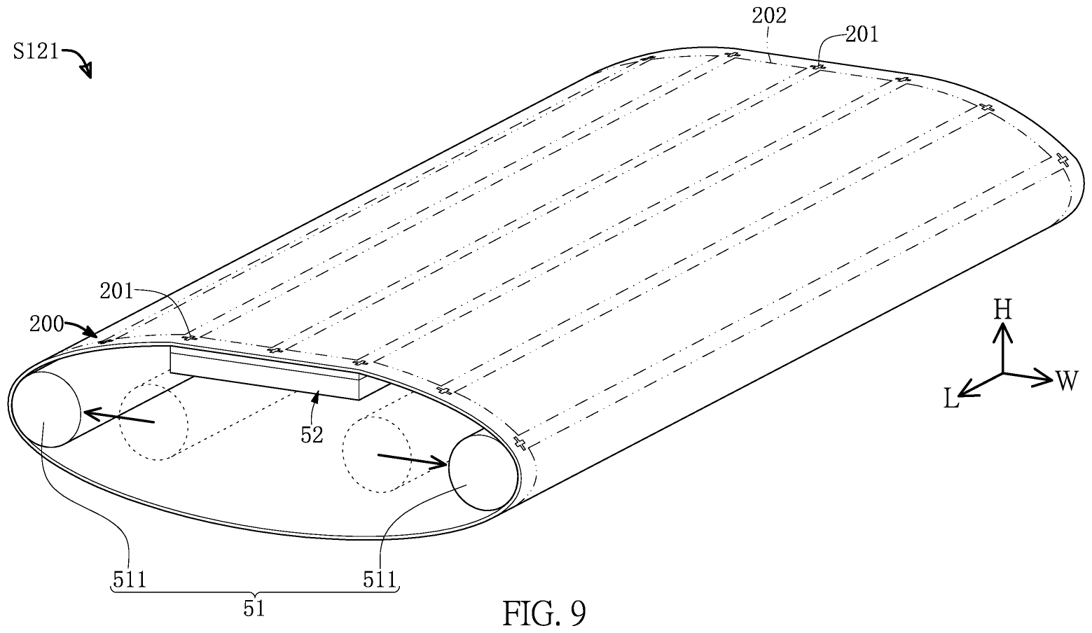

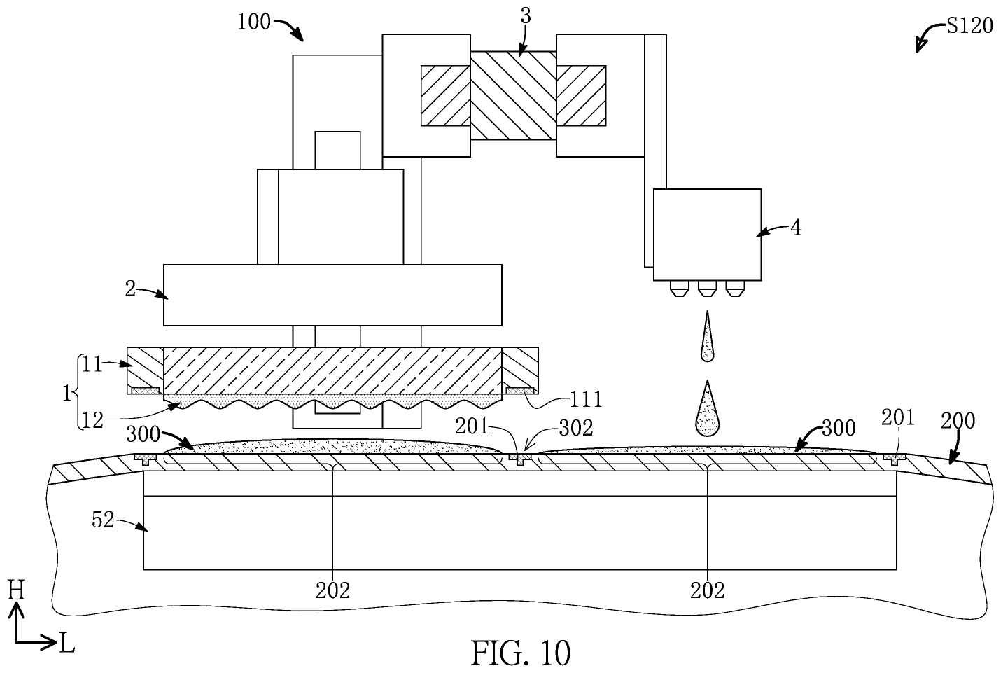

Referring to FIG. 8 to FIG. 10, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the alignment carrier 200 has a hollow cylindrical shape, and the embossing mask 1 has an elongated shape. Moreover, a length of the unit pattern layer 12 is at least 80% of a length of the alignment carrier 200 along a longitudinal direction thereof, and the one of the hologram unit patterns 301 is parallel to the longitudinal direction of the alignment carrier 200.

Specifically, before the embossing and solidifying step S120 is implemented, the alignment forming method further includes a flattening step S121 implemented by forcing the alignment carrier 200 from an inner side thereof to elastically deform the alignment carrier 200 to have a flattened shape. Moreover, in the embossing and solidifying step S120, one of the embossed regions 202 can be suctioned from the inner side of the alignment carrier 200 to flatten the one of the embossed regions 202.

In the present embodiment, the alignment forming apparatus 100 (or the platform) further includes a flattening mechanism 51 and a suction mechanism 52 that is in cooperation with the flattening mechanism 51. Moreover, the flattening mechanism 51 and the suction mechanism 52 in the present embodiment can be regarded as components of the platform (not shown in the drawings). The flattening mechanism 51 is disposed in and pushes the inner side of the alignment carrier 200 so as to elastically deform the alignment carrier 200 to have the flattened shape. The suction mechanism 52 is disposed in the inner side of the alignment carrier 200 and is operated to suction the one of the embossed regions 202 of the alignment carrier 202 to flatten the one of the embossed regions 202.

In the present embodiment, the flattening mechanism 51 includes a plurality of rollers 511 disposed in the inner side of the alignment carrier 200. The rollers 511 (in the flattening step S121) are operated to enable the alignment carrier 200 to have the flattened shape, and the rollers 511 (in the embossing and solidifying step S120) are operated to rotate the alignment carrier 200 so as to allow the embossed regions 202 to be sequentially suctioned by the suction mechanism 52.

In summary, the alignment forming method provided by the present embodiment can be implemented to rapidly form the hologram unit patterns 301 by using the alignment carrier 200 that has the hollow cylindrical shape through the flattening step S121, and can be implemented to precisely form the hologram unit patterns 301 through the cooperation between the mask alignment marks 111 of the embossing mask 1 and the carrier alignment marks 201 of the alignment carrier 200.

### Beneficial Effects of the Embodiments

In conclusion, the alignment forming method provided by the present disclosure can be implemented to rapidly form the hologram unit patterns without using the conventional rolling manner, and can be implemented to precisely form the hologram unit patterns through the cooperation between the mask alignment marks of the embossing mask and the carrier alignment marks of the alignment carrier.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An alignment forming method for a hologram film, comprising:
a preparing step implemented by providing:
an embossing mask including a plate and a unit pattern layer that is formed on the plate, wherein the plate has a plurality of mask alignment marks corresponding in position to the unit pattern layer; and
an alignment carrier having a plurality of carrier alignment marks, wherein the alignment carrier defines a plurality of embossed regions through the carrier alignment marks; and
an embossing and solidifying step implemented by sequentially placing a plurality of ultraviolet (UV) solidified resins onto the embossed regions, respectively, and sequentially embossing the UV solidified resins in a plurality of embossing processes to enable the UV solidified resins to respectively have a plurality of hologram unit patterns;
wherein, one of the embossing processes is implemented by aligning the mask alignment marks of the embossing mask with at least two of the carrier alignment marks arranged adjacent to one of the UV solidified resins along a height direction, and then embossing the one of the UV solidified resins along the height direction through the unit pattern layer of the embossing mask so as to enable the one of the UV solidified resins to have a predetermined unit pattern;
wherein, in the embossing and solidifying step, when the one of the UV solidified resins is embossed through the embossing mask, the predetermined unit pattern of the one of the UV solidified resins is solidified to form one of the hologram unit patterns by a solidifying UV light; and
wherein the UV solidified resins are spaced apart from each other, and any two of the UV solidified resins adjacent to each other have an alignment gap therebetween that is less than or equal to 5 μm and that is provided for allowing at least one of the carrier alignment marks to be exposed therefrom.

2. The alignment forming method according to claim 1, wherein, in any two of the embossing processes, two of the UV solidified resins are embossed to flow outwardly and fill the alignment gap therebetween for covering a corresponding one of the carrier alignment marks.

3. The alignment forming method according to claim 1, wherein the alignment carrier has a hollow cylindrical shape; and wherein, before the embossing and solidifying step is implemented, the alignment forming method further includes a flattening step implemented by forcing the alignment carrier from an inner side thereof to elastically deform the alignment carrier to have a flattened shape.

4. The alignment forming method according to claim 3, wherein, in the embossing and solidifying step, a suction mechanism is disposed in the inner side of the alignment carrier and is operated to suction one of the embossed regions of the alignment carrier to flatten the one of the embossed regions.

5. The alignment forming method according to claim 4, wherein, in the flattening step, a plurality of rollers are disposed in the inner side of the alignment carrier and are operated to enable the alignment carrier to have the flattened shape; and wherein, in the embossing and solidifying step, the alignment carrier is rotated through the rollers to allow the embossed regions to be sequentially suctioned by the suction mechanism.

6. The alignment forming method according to claim 3, wherein the embossing mask has an elongated shape, a length of the unit pattern layer is at least 80% of a length of the alignment carrier along a longitudinal direction thereof, and the one of the hologram unit patterns is parallel to the longitudinal direction.

7. The alignment forming method according to claim 1, wherein the alignment carrier has a flat shape, and the hologram unit patterns are in a matrix arrangement.

8. The alignment forming method according to claim 1, wherein the unit pattern layer is formed by using an exposure UV light to irradiate onto a photoresist layer through a mask or an interference, and wherein a predetermined exposing wavelength of the exposure UV light is not in a predetermined solidifying wavelength band of the solidifying UV light, and the predetermined exposing wavelength of the exposure UV light is less than the predetermined solidifying wavelength band of the solidifying UV light by at least 100 nm.

9. The alignment forming method according to claim 8, wherein, after the embossing and solidifying step is implemented, the alignment forming method further includes a mask correcting step implemented by using an optical proximity correction (OPC) process to manufacture a corrected embossing mask according to the predetermined unit pattern, and wherein the mask correcting step includes:
forming another photoresist layer on another plate;
adjusting an intensity distribution of the exposure UV light through the OPC process; and
using the exposure UV light being adjusted to have a predetermined light shape through the mask or the interference, and then irradiating the exposure UV light having the predetermined light shape onto the another photoresist layer for forming a corrected unit pattern layer, wherein the corrected unit pattern layer and the another plate are jointly formed as the corrected embossing mask.

10. The alignment forming method according to claim 1, wherein, in the embossing and solidifying step, when another one of the UV solidified resins is embossed through the embossing mask, the hologram unit pattern of the another one of the UV solidified resins is solidified by the solidifying UV light that has an intensity distribution adjusted by an OPC process according to the predetermined unit pattern.
